(19) United States
(12) Patent Application Publication
(10) Pub. No.: US 2025/0273976 A1
(43) Pub. Date: Aug. 28, 2025

(54) POWER MANAGEMENT CIRCUIT HAVING CAPACITOR MONITORING FUNCTION

(71) Applicant: Chengdu Monolithic Power Systems Co., Ltd., Chengdu (CN)

(72) Inventors: Bo Li, Chengdu (CN); Hang Yang, Chengdu (CN); Yong Zhou, Chengdu (CN); Pengjie Lai, San Jose, CA (US)

(21) Appl. No.: 19/062,934

(22) Filed: Feb. 25, 2025

(30) Foreign Application Priority Data
Feb. 27, 2024 (CN) 202410224226.3

(51) Int. Cl. H02J 7/00

(52) U.S. Cl. CPC H02J 7/0047; H02J 7/00712; H02J 2207/20; H02J 2207/50

(57) ABSTRACT

The present disclosure provides a power management circuit. The power management circuit includes a power converter circuit and a discharging circuit. The power converter circuit can convert a bus voltage to a terminal voltage at a terminal adapted to couple an energy storage capacitor, and the discharging circuit may be controllable to provide a discharge path for the energy storage capacitor. By using this power management circuit, the capacitance value of the energy storage capacitor can be monitored effectively.

### CROSS-REFERENCE TO RELATED APPLICATIONS

This application claims the benefit of CN application No. 202410224226.3 filed on Feb. 27, 2024 and incorporated herein by reference.

### TECHNICAL FIELD

The present invention relates to a power management circuit.

### BACKGROUND OF THE INVENTION

Power management circuits that include power converter circuits and energy storage capacitors can have energy storage functions. The power management circuit controls the power converter circuit to charge the energy storage capacitor. When there is power loss in a system in which the power management circuit is included, a power supply to the system or to the power management circuit is interrupted or a supply voltage drops below the level required to maintain normal operations, the energy stored on the energy storage capacitor can be used as a backup power source to provide power for the power management circuit.

According to the principle of capacitors, the energy stored in an energy storage capacitor is proportional to the capacitance value of the capacitor. However, capacitors will age over time, and their capacitance value will decrease, resulting in a corresponding decline of their energy storage capability. In some applications, when the energy stored in the energy storage capacitor is reduced to a certain extent, it will no longer be able to serve as a backup power source. Therefore, it is necessary to effectively monitor the energy storage capacitor, more specifically, monitor the capacitance value of the energy storage capacitor and minimize the impact of monitoring actions on normal functionality.

### SUMMARY OF THE INVENTION

Embodiments of this invention relates to a power management circuit. The power management circuit includes a power converter circuit configured to be coupled to an energy storage capacitor and a discharge circuit configured to be coupled to the energy storage capacitor. The power converter is configured to convert a bus voltage to a terminal voltage and allow the terminal voltage to reach and maintain at a preset storge value or to reach at a preset overcharged value which is higher than the preset storge value.

Embodiments of this invention relates to a power management circuit. The power management circuit includes a power converter circuit configured to be coupled to an energy storage capacitor and a controllable discharge circuit configured to be coupled to the energy storage capacitor. The controllable discharge circuit is configured to allow a terminal voltage to decrease at a first rate or at a second rate. A magnitude of the first rate is different from that of the second rate.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is a schematic diagram of a power management circuit 100 according to an embodiment of the present disclosure.

FIG. 2 is a schematic waveform of a terminal voltage V_strg according to an embodiment of the present disclosure.

FIG. 3 is another schematic diagram of the power management circuit 100 according to another embodiment of the present disclosure.

FIG. 4 is another schematic waveform of the terminal voltage V_strg according to another embodiment of the present disclosure.

FIG. 5 is a schematic waveform of the terminal voltage V_strg according to one embodiment of the present disclosure.

FIG. 6 is a schematic waveform of the terminal voltage V_strg according to one embodiment of the present disclosure.

FIG. 7 is a schematic waveform of the terminal voltage V_strg according to one embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of the present application described herein will be apparent. Description of materials and methods that are known in the art may not be addressed in the present application for simplicity.

Throughout the specification and claims, the phrases “in one embodiment”, “in some embodiments”, “in one implementation”, and “in some implementations” as used include both combinations and sub-combinations of various features described herein as well as variations and modifications thereof. These phrases used herein do not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale. For example, although change in an amplitude of the terminal voltage V_strg on the energy storage capacitor C_{STRG} during a capacitance monitoring period in the drawings is illustratively shown to be significant relative to a preset storge value VS, those skilled in the art should understand that it can actually be small and moderate.

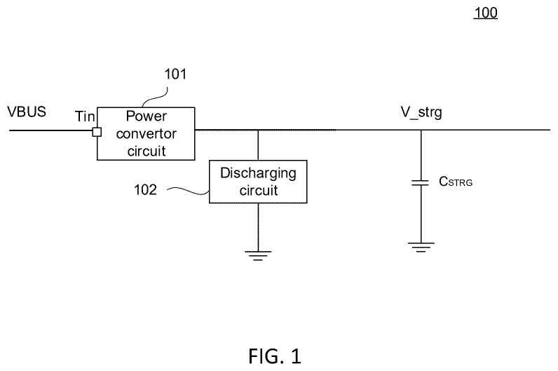

FIG. 1 is a schematic diagram of a power management circuit 100. The power management circuit 100 includes a power converter circuit 101 configured to be coupled to an energy storage capacitor C_{STRG}. The power converter circuit 101 can include a boost circuit, a buck circuit, a buck-boost circuit, etc. The energy storage capacitor C_{STRG} can be an electrolytic capacitor, a layered capacitor, a tantalum capacitor, a double-layer capacitor, a high molecular capacitor, or a battery. As the energy storage capacitor C_{STRG} ages, the amount of energy that the energy storage capacitor C_{STRG} can store gradually decreases. When the energy that the energy storage capacitor C_{STRG} can store reduces to a certain extent, the energy storage capacitor C_{STRG} will no longer be able to serve as backup power source. For example, when the power management circuit 100 is used to provide power for non-volatile semiconductor memory, the energy storage capacitor C_{STRG} is used to provide power loss protection for the memory when a system power loss occurs, and the energy stored in the energy storage capacitor C_{STRG} should be always sufficient to meet the needs of data backup. In some applications, if the capacitance value of the energy storage capacitor C_{STRG} decreases to a point where the memory no longer has a backup capability, the memory will be considered to have reached the end of its life. For such applications, a threshold value is usually set for the capacitance value of the energy storage capacitor C_{STRG}, and the capacitance value is regularly monitored.

As shown in FIG. 1, in accordance with an exemplary embodiment of the present disclosure, the power management circuit 100 includes the power converter circuit 101 configured to be coupled to the energy storage capacitor C_{STRG} and a discharging circuit 102 configured to be coupled to the energy storage capacitor C_{STRG}. The power converter circuit 101 comprises an input terminal Tin to receive a bus voltage VBUS and the power converter circuit 101 is configured to convert the received bus voltage VBUS to a terminal voltage V_strg on the energy storage capacitor C_{STRG}. For example, the power converter circuit 101 may regulate a voltage level (or voltage amplitude) of the terminal voltage V_strg to a preset storge value VS or a preset overcharged value V0, and the preset overcharged value V0 is higher than the preset storge value VS.

In accordance with an exemplary embodiment of the present disclosure, under normal operating mode conditions, the power converter circuit 101 is configured to charge the energy storage capacitor C_{STRG} and allow the terminal voltage V_strg to reach and maintain at the preset storge value VS, while under capacitance monitoring mode conditions, the power converter circuit 101 is configured to overcharge the energy storage capacitor C_{STRG} and allow the terminal voltage V_strg to reach the preset overcharged value V0. The preset overcharged value V0 is higher than the preset storge value VS.

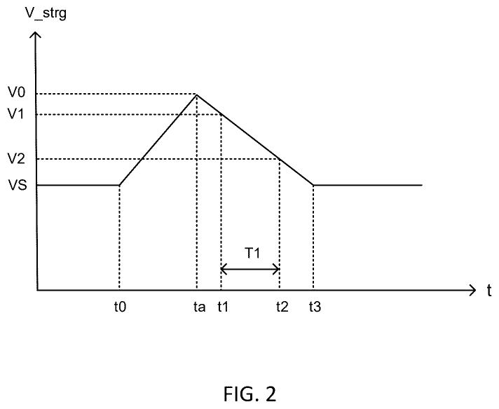

Under the normal operating mode conditions, the discharging circuit 102 is disabled, while under the capacitance monitoring mode conditions, at least during some period of time, the discharging circuit 102 is enabled to provide a discharge path for the energy storage capacitor C_{STRG}. As shown in FIG. 2, in accordance with an exemplary embodiment of the present disclosure, the capacitance monitoring mode begins at a moment t0, when the power converter circuit 101 begins to overcharge the terminal voltage V_strg to make the terminal voltage V_strg increase until the terminal voltage V_strg reaches the preset overcharged value V0 which exceeds a first threshold voltage V1. Subsequently, the power management circuit 100 controls the discharging circuit 102 to discharge the energy storage capacitor C_{STRG}, during which the discharging circuit 102 is configured to provide a first constant discharge current I_dis1.

The power management circuit 100 is further configured to sense and monitor the terminal voltage V_strg during a discharging period of the capacitance monitoring mode. Referring to FIG. 2, the discharging period of the capacitance monitoring mode begins at a moment ta and ends at a moment t3. During the discharging period of the capacitance monitoring mode, the voltage level of the terminal voltage V_strg gradually decreases from the preset overcharged value V0. At a moment t1, it decreases to the first threshold voltage V1, and at a moment t2, it decreases to a second threshold voltage V2. The time T1 that it takes for the terminal voltage V_strg to decrease from the first threshold voltage V1 to the second threshold voltage V2 could be counted and provided for instance by a timing circuit. In one embodiment of the present disclosure, the first threshold voltage V1 is set to be higher than the second threshold voltage V2 and the second threshold voltage V2 is set to be higher than the preset storge value VS, while in another embodiment of the present disclosure, the first threshold voltage V1 is set to be higher than the second threshold voltage V2 and the second threshold voltage V2 is set to be lower than the preset storge value VS.

By overcharging the terminal voltage V_strg to the preset overcharged value V0 and counting the time T1 that it takes for the terminal voltage V_strg to decrease from the first threshold voltage V1 to the second threshold voltage V2, a capacitance of the energy storage capacitor C_{STRG}, C1, can be expressed by a following equation (1):

$$C 1 = I\_dis 1 * T 1 / ( V 1 - V 2 ) \qquad ( 1 )$$

In the equation (1), the I_dis1 represents the first constant discharge current determined by presetting the discharging circuit 102, V1 and V2 are two preset values, T1 is measured during the discharging period of the capacitance monitoring mode. That is to say, all these parameters can be preset or measured during the capacitance monitoring mode, therefore the capacitance C1 can be calculated based on the equation (1) by any module with computational capabilities.

Referring to FIG. 2, at the moment t3 when the capacitance monitoring mode ends, the terminal voltage V_strg decreases to the preset storge value VS, the discharging circuit 102 is configured to be disabled and stops to operate, so that the power management circuit 100 is configured to work in a normal operating mode and the voltage level of the terminal voltage V_strg is converted and maintained at the preset storge value VS by the power converter circuit 101. In accordance with the embodiment of FIG. 2, in the whole duration of the capacitance monitoring mode (i.e., from the moment t0 to the moment t3), the voltage level of the terminal voltage V_strg is always kept no lower than the preset storge value VS, so that when there is power loss, namely the power supply to the power management circuit is interrupted or the supply voltage drops below the level required to maintain normal operations, the energy stored on the energy storage capacitor C_{STRG} would be enough to support the power management circuit 100 to operate for an extra time period to allow a load (for example a memory device) powered by the power management circuit 100 to take any actions.

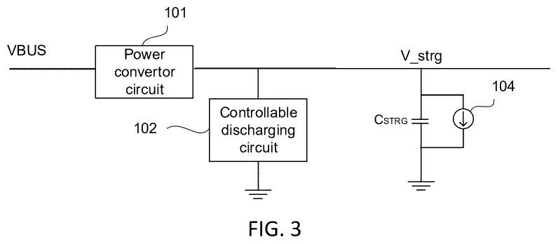

In accordance with another embodiment as shown in FIG. 3, the power management circuit 100 includes the power converter circuit 101 configured to be coupled to the energy storage capacitor C_{STRG} and a controllable discharging circuit 102 configured to be coupled to the energy storage capacitor C_{STRG}. The power converter circuit 101 is configured to convert the bus voltage VBUS to the terminal voltage V_strg on the energy storage capacitor C_{STRG}. For example, when the power management circuit 100 is configured to work in the normal operating mode, the voltage level of the terminal voltage V_strg is regulated and maintained at the preset storge value VS by the power converter circuit 101.

FIG. 3 also shows an additional current source 104 coupled in parallel with the energy storage capacitor C_{STRG}. It should be noted that the present embodiment of FIG. 3 of the present disclosure doesn't actually implement the additional current source 104 to be coupled to the energy storage capacitor C_{STRG}. This illustration of the additional current source 104 is intended to equivalently represent the leakage phenomenon of capacitors since a concept of the present disclosure is intended to equivalently represent the leakage current of the energy storage capacitor C_{STRG} as a constant current source 104 with a constant current I_lkg.

In some embodiments of the present disclosure, the controllable discharging circuit 102 is coupled to the energy storage capacitor C_{STR} to provide the discharge path for the energy storage capacitor C_{STRG}, so that the terminal voltage V_strg could be controlled to decrease with a first rate or with a second rate based on a control signal that the controllable discharging circuit 102 received. The magnitude of the first rate is different from that of the second rate.

In some embodiments of the present disclosure, the controllable discharging circuit 102 is configured to provide at least a second constant current I_dis2 and a third constant current I_dis3, wherein the magnitudes of the second constant current I_dis2 and the third constant current I_dis3 are different and they have a proportional relationship. As mentioned before, the power management circuit 100 is configured to have the normal operating mode and the capacitance monitoring mode. In some following embodiments of the present disclosure, when the power management circuit 100 is configured to work in the normal operating mode, the controllable discharging circuit 102 is configured to be disabled; when the power management circuit 100 is configured to work in the capacitance monitoring mode, in two separate capacitance monitoring durations of the capacitance monitoring mode, the controllable discharging circuit 102 is configured to provide the discharge path for the energy storage capacitor C_{STRG} with the second constant current I_dis2 or the third constant current I_dis3, respectively.

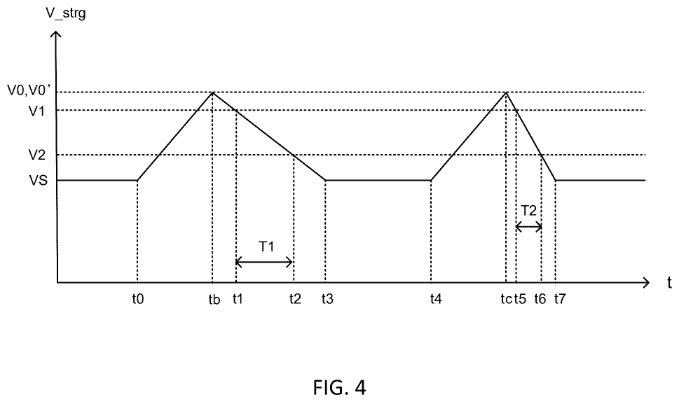

As shown in FIG. 4, in an exemplary embodiment of the present disclosure, there is a first capacitance monitoring duration (i.e., from the moment t0 to the moment t3) of the capacitance monitoring mode and a second capacitance monitoring duration (i.e., from the moment t4 to the moment t7) of the capacitance monitoring mode. The first capacitance monitoring duration begins at the moment t0, when the power converter circuit 101 begins to overcharge the terminal voltage V_strg and to make the terminal voltage V_strg increase until the terminal voltage V_strg reaches the preset overcharged value V0 which exceeds a first threshold voltage V1. Subsequently, a discharging period starts from the moment tb, the power management circuit 100 controls the controllable discharging circuit 102 to discharge the energy storage capacitor C_{STRG}. During the discharging period of the first capacitance monitoring duration, the controllable discharging circuit 102 is configured to provide the second constant discharge current I_dis2, allowing the terminal voltage V_strg to decrease with a first rate.

The power management circuit 100 is further configured to sense and monitor the terminal voltage V_strg during the discharging period of the first capacitance monitoring duration. Referring to FIG. 4, the discharging period of the first capacitance monitoring duration begins at a moment tb and ends at a moment t3. During the discharging period of the first capacitance monitoring duration, the voltage level of the terminal voltage V_strg gradually decreases from the preset overcharged value V0. At the moment time t1, it decreases to the first threshold voltage V1, and at the moment time t2, it decreases to the second threshold voltage V2. The time T1 that it takes for the terminal voltage V_strg to decrease from the first threshold voltage V1 to the second threshold voltage V2 could be counted and provided for instance by the timing circuit. In one embodiment of the present disclosure, the first threshold voltage V1 is set to be higher than the second threshold voltage V2 and the second threshold voltage V2 is set to be higher than the preset storge value VS, while in another embodiment of the present disclosure, the first threshold voltage V1 is set to be higher than the second threshold voltage V2 and the second threshold voltage V2 is set to be lower than the preset storge value VS.

Considering the presence of leakage current I_lkg of the energy storage capacitor C_{STR}, during the time T1, the change in charge on the energy storage capacitor C_{STRG}, ΔQ1, can be expressed by a following equation (2):

$$Δ Q 1 = C 1 * ( V 1 - V 2 ) = ( I\_dis2 + I\_lkg ) * T 1 \qquad ( 2 )$$

The second capacitance monitoring duration begins at a moment t4, when the power converter circuit 101 begins to overcharge the terminal voltage V_strg and to make the terminal voltage V_strg increase until the terminal voltage V_strg reaches a preset overcharged value V0′ which exceeds a first threshold voltage V1. Subsequently, a discharging period of the second capacitance monitoring duration starts at a moment tc, the power management circuit 100 controls the discharging circuit 102 to discharge the energy storage capacitor C_{STRG}. During the discharging period of the second capacitance monitoring duration, the discharging circuit 102 is configured to provide the third constant discharge current I_dis3, allowing the terminal voltage V_strg to decrease with a second rate. As mentioned above, the magnitudes of the second constant current I_dis2 and the third constant current I_dis3 are different and they have a proportional relationship. In other words, the relationship of the second constant current I_dis2 and the third constant current I_dis3 could be expressed by a following equation (3):

$$I\_dis3 = A * I\_dis2 , \qquad ( 3 )$$

wherein the parameter A represents a ratio between the third constant current I_dis3 and the second constant current I_dis2, and A≠1.

Referring to FIG. 4, the discharging period of the second capacitance monitoring duration begins at the moment tc and ends at a moment t7. During the discharging period of the second capacitance monitoring duration, the voltage level of the terminal voltage V_strg gradually decreases from the preset overcharged value V0′. At a moment time t5, it decreases to the first threshold voltage V1, and at the moment time t6, it decreases to the second threshold voltage V2. A time T2 that it takes for the terminal voltage V_strg to decrease from the first threshold voltage V1 to the second threshold voltage V2 during the discharging period of the second capacitance monitoring duration could be counted and provided for instance by the timing circuit.

Considering the presence of leakage current I_lkg of the energy storage capacitor C_{STR}, the change in charge on the energy storage capacitor C_{STRG} during the time T2, ΔQ2, can be expressed by a following equation (4):

$$Δ Q 2 = C 1 * ( V 1 - V 2 ) = ( I\_dis3 + I\_lkg ) * T 2 = ( A * I\_dis2 + I\_lkg ) * T 2 \qquad ( 4 )$$

During the time T1 and the time T2, the changes in charge on the energy storage capacitor C_{STRG}, both ΔQ1 and ΔQ2, are C1*(V1−V2). Therefore, considering the equation (2), (3) and (4), the capacitance C1 of the energy storage capacitor C_{STRG} can be expressed by a following equation (5):

$$C 1 = ( A - 1 ) * T 1 * T 2 * I\_dis2 / ( T 1 - T 2 ) * ( V 1 - V 2 ) \qquad ( 5 )$$

In the equation (5), the parameter A is the ratio between the third constant current I_dis3 and the second constant current I_dis2, the second constant current I_dis2 is provided by the discharging circuit 102, V1 and V2 are two preset values, T1 and T2 are measured during the discharging period of the first capacitance monitoring duration or the second capacitance monitoring duration. That is to say, all these parameters can be preset or measured during the capacitance monitoring mode, therefore the capacitance C1 can be calculated based on the equation (5).

In the exemplary embodiment of FIG. 4, the preset overcharged value V0 and V0′ are set to be equal, while in other embodiments, they could be set to be different.

In another embodiment of the present disclosure, both the actions of the power management circuit 100 and a waveform of the terminal voltage V_strg during the first capacitance monitoring duration are the same as those of the embodiment of FIG. 4, the difference lies in the discharging period of the second capacitance monitoring duration. During the discharging period of the second capacitance monitoring duration, the voltage level of the terminal voltage V_strg gradually decreases from the preset overcharged value V0′. At a moment time t5, it decreases to a third threshold voltage V3 (not shown), and at the moment time t6, it decreases to a fourth threshold voltage V4 (not shown). The difference between the third threshold voltage V3 and the fourth threshold voltage V4, (V3−V4), has a proportional relationship with the difference between the first threshold voltage V1 and the second threshold voltage V2, (V1−V2). That is to say, (V3−V4)=B*(V1−V2), wherein the parameter B represents a ratio between (V3−V4) and (V1−V2). One of ordinary skill in the art would understand and derive the expression for the capacitance C1 of the energy storage capacitor C_{STRG} based on the same principles as described above with reference to FIG. 4 and there's no need to repeat those descriptions here. In one embodiment, the third threshold voltage V3 is set to be higher than the fourth threshold voltage V4 and the fourth threshold voltage V4 is set to be higher than the preset storge value VS, while in another embodiment of the present disclosure, the third threshold voltage V3 is set to be higher than the fourth threshold voltage V4 and the fourth threshold voltage V4 is set to be lower than the preset storge value VS.

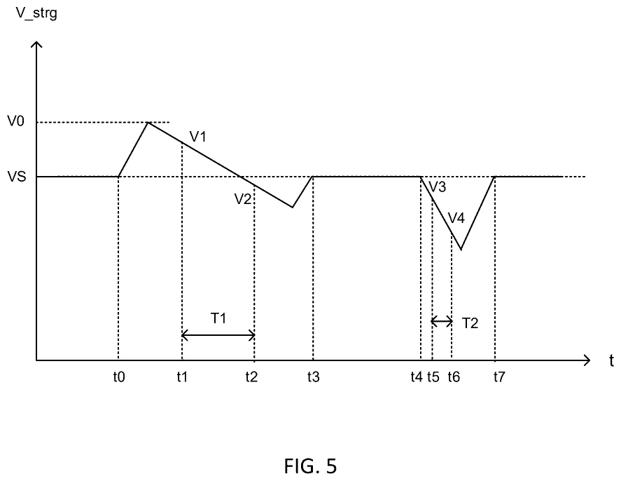

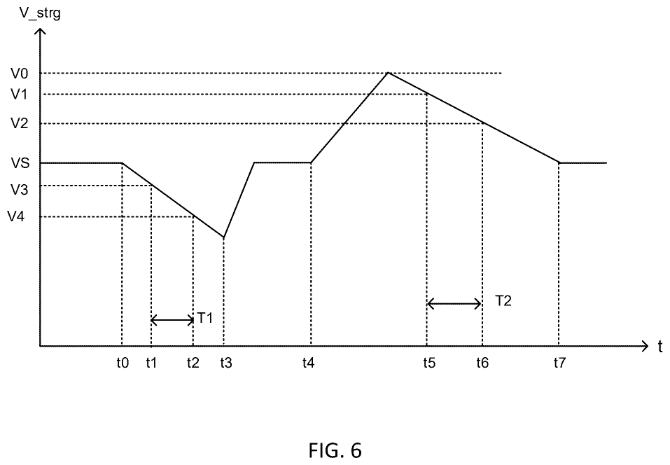

FIG. 5 and FIG. 6 show other embodiments of the present disclosure. In these embodiments, the capacitance monitoring mode also have at least two capacitance monitoring durations. During one of the capacitance monitoring durations, the energy storage capacitor C_{STRG} is configured to be overcharged and the terminal voltage V_strg is configured to reach the preset overcharged value V0, while in another capacitance monitoring duration, the energy storage capacitor C_{STRG} is configured to be directly discharged without being overcharged.

Taking FIG. 5 as an exemplary embodiment of such capacitance monitoring mode, during the first capacitance monitoring duration (from the moment t0 to the moment t3), the actions of the power management circuit 100 are similar as those described with the reference of FIG. 4, the second constant current I_dis2 is provided as the discharging current. Therefore, in the embodiment of FIG. 5, considering the presence of leakage current I_lkg of the energy storage capacitor C_{STR}, during the T1 time, the change in charge on the energy storage capacitor C_{STR}, ΔQ1, can also be expressed by the equation (2) described above. During the second capacitance monitoring duration (from the moment t4 to the moment t7), the power management circuit 100 controls the discharging circuit 102 to directly discharge the energy storage capacitor C_{STR} with the third constant current I_dis3, without overcharging the energy storage capacitor C_{STR} and allowing the terminal voltage V_strg to reach the preset overcharged value V0. The magnitudes of the second constant current I_dis2 and the third constant current I_dis3 have a proportional relationship as expressed by the equation (3) described above. At the moment time t5, the terminal voltage V_strg decreases to the third threshold voltage V3, and at the moment time t6, it decreases to the fourth threshold voltage V4. The difference between the third threshold voltage V3 and the fourth threshold voltage V4, (V3−V4), has a proportional relationship with the difference between the first threshold voltage V1 and the second threshold voltage V2, (V1−V2). Therefore, in the embodiment of FIG. 5, considering the presence of leakage current I_lkg of the energy storage capacitor C_{STR}, during the time T2 (from the moment t3 to the moment t4), the change in charge on the energy storage capacitor C_{STR}, ΔQ2, can be expressed by an equation (6):

$$Δ Q 2 = C 1 * ( V 3 - V 4 ) = ( I\_dis3 + I\_lkg ) * T 2 = ( A * I\_dis2 + I\_lkg ) * T 2 \qquad ( 6 )$$

One of ordinary skill in the art would understand and derive the expression for the capacitance C1 of the energy storage capacitor C_{STRG} in this embodiment based on the same principles as described above with reference to FIG. 4 and there's no need to repeat those descriptions here.

In some embodiments, one of ordinary skill in the art could set the first threshold voltage V1 and the second threshold voltage V2 with reference to FIG. 6, letting the first threshold voltage V1 to be higher the second threshold voltage V2 and the second threshold voltage V2 to be higher than the preset storge value VS, or set the first threshold voltage V1 and the second threshold voltage V2 with reference to FIG. 5, letting the first threshold voltage V1 to be higher the second threshold voltage V2 and the second threshold voltage V2 to be lower than the preset storge value VS.

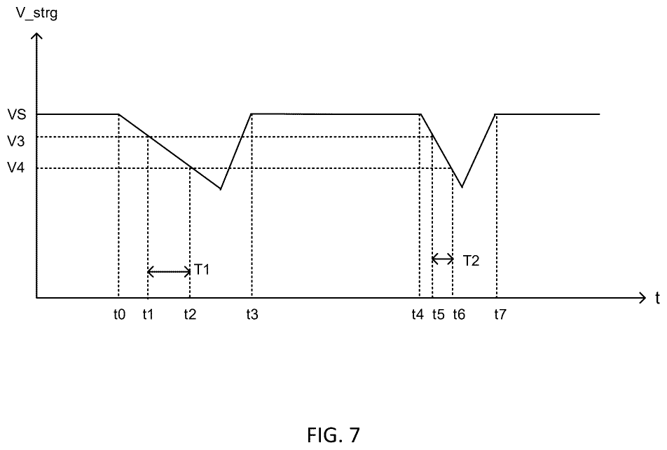

FIG. 7 shows another embodiment of the present disclosure. In this embodiment, the capacitance monitoring mode also have at least two capacitance monitoring durations, however, during these capacitance monitoring durations, the energy storage capacitor C_{STRG} is configured to be directly discharged without being overcharged. For example, during the first capacitance monitoring duration (from the moment t0 to the moment t3), the power management circuit 100 controls the discharging circuit 102 to directly discharge the energy storage capacitor C_{STR} with the second constant current I_dis2, without overcharging the energy storage capacitor C_{STR} and allowing the terminal voltage V_strg to reach the preset overcharged value V0. At the moment time t1, the terminal voltage V_strg decreases to the third threshold voltage V3 which is set to be lower than the preset storge value VS, and at the moment time t2, it decreases to the fourth threshold voltage V4 which is also set to be lower than preset storge value VS. Therefore, in the embodiment of FIG. 7, considering the presence of leakage current I_lkg of the energy storage capacitor C_{STR}, during the time T1 (from the moment t1 to the moment t2), the change in charge on the energy storage capacitor C_{STR}, ΔQ1, can be expressed by an equation (7):

$$Δ Q 1 = C 1 * ( V 3 - V 4 ) = ( I\_dis2 + I\_lkg ) * T 1. \qquad ( 7 )$$

During the second monitoring duration (from the moment t4 to the moment t7), the power management circuit 100 controls the discharging circuit 102 to directly discharge the energy storage capacitor C_{STR} with the third constant current I_dis3, without overcharging the energy storage capacitor C_{STR} and allowing the terminal voltage V_strg to reach the preset overcharged value V0. At the moment time t5, the terminal voltage V_strg decreases to the third threshold voltage V3 which is set to be lower than the preset storge value VS, and at the moment time t6, it decreases to the fourth threshold voltage V4 which is also set to be lower than preset storge value VS. Therefore, in the embodiment of FIG. 7, considering the presence of leakage current I_lkg of the energy storage capacitor C_{STR}, during the time T2 (from the moment t5 to the moment t6), the change in charge on the energy storage capacitor C_{STR}, ΔQ2, can be expressed by an equation (8):

$$Δ Q 2 = C 1 * ( V 3 - V 4 ) = ( I\_dis3 + I\_lkg ) * T 2. \qquad ( 8 )$$

The same as definition described above, the magnitudes of the second constant current I_dis2 and the third constant current I_dis3 are different and they have a proportional relationship. One of ordinary skill in the art would understand and derive the expression for the capacitance C1 of the energy storage capacitor C_{STRG} in this embodiment based on the same principles as described above and there's no need to repeat those descriptions here. In the embodiment of FIG. 7, the timing circuit 103 is configured to provide the time T1 and the time T2 that it takes for the terminal voltage V_strg to decrease from the third threshold voltage V3 to the fourth threshold voltage V4. In another embodiment, it's not necessary to use the same threshold voltages in different discharging periods. That is to say, in another embodiment, the time that it takes for the terminal voltage V_strg to decrease from the first threshold voltage V1 to the second threshold voltage V2 may be provided as the time T1 and the time that it takes for the terminal voltage V_strg to decrease from the third threshold voltage V3 to the fourth threshold voltage V4 may be provided as the time T2, as long as the difference between the third threshold voltage V3 and the fourth threshold voltage V4, (V3−V4), has a proportional relationship with the difference between the first threshold voltage V1 and the second threshold voltage V2, (V1−V2).

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A power management circuit, comprising:
a power converter circuit configured to be coupled to an energy storage capacitor; and
a discharge circuit configured to be coupled to the energy storage capacitor;
wherein the power converter is configured to regulate a voltage level of a terminal voltage to a preset storge value or a preset overcharged value;
wherein the preset overcharged value is higher than the preset storge value; and
wherein the power management circuit includes a normal operating mode and a capacitance monitoring mode, and wherein the power converter circuit is configured to regulate the terminal voltage to reach and maintain at the preset storge value in the normal operating mode and further configured to regulate the terminal voltage to reach at the preset overcharged value in the capacitance monitoring mode.

2. The power management circuit as claimed in claim 1, the discharge circuit is configured to be disabled in the normal operating mode and the discharge circuit is configured to be enabled at least during some period of time in the capacitance monitoring mode.

3. The power management circuit as claimed in claim 1, wherein the power management circuit includes a timing circuit, wherein the timing circuit is configured to provide the time that it takes for the terminal voltage to decrease from a first threshold voltage to a second threshold voltage, and wherein the first threshold voltage is higher than the second threshold voltage.

4. A power management circuit, comprising:
a power converter circuit configured to convert a bus voltage to a terminal voltage; and
a controllable discharge circuit configured to be enabled at least twice to discharge the terminal voltage in a capacitance monitoring mode of the power management circuit;
wherein the controllable discharge circuit is configured to allow the terminal voltage to decrease with a first rate or with a second rate, and wherein the first rate is different from that of the second rate.

5. The power management circuit as claimed in claim 4, the controllable discharge circuit is configured to be able to provide a second constant current and a third constant current, wherein the magnitudes of the second constant current and the third constant current are different and they have a proportional relationship.

6. The power management circuit as claimed in claim 4, wherein the power management circuit further includes a normal operating mode; and wherein in the normal operating mode, the controllable discharge circuit is configured disabled, and the power converter is configured to convert the bus voltage to the terminal voltage and allow the terminal voltage to reach and maintain at a preset storge value.

7. The power management circuit as claimed in claim 4, wherein the capacitance monitoring mode having at least a first capacitance monitoring duration and a second capacitance monitoring duration; and wherein in a discharging period of the first capacitance monitoring duration, the terminal voltage decreases with the first rate, and wherein in a discharging period of the second capacitance monitoring duration, the terminal voltage decreases with the second rate.

8. The power management circuit as claimed in claim 6, wherein the capacitance monitoring mode having at least a first capacitance monitoring duration and a second capacitance monitoring duration; and wherein in the first capacitance monitoring duration, the power converter circuit is configured to allow the terminal voltage to reach at a first preset overcharged value which is higher than the preset storge value.

9. The power management circuit as claimed in claim 6, wherein the capacitance monitoring mode having at least a first capacitance monitoring duration and a second capacitance monitoring duration; and wherein in the second capacitance monitoring duration, the power converter circuit is configured to allow the terminal voltage to reach at a second preset overcharged value which is higher than the preset storage value.

10. The power management circuit as claimed in claim 6, wherein the capacitance monitoring mode having at least a first capacitance monitoring duration and a second capacitance monitoring duration; and wherein in the first capacitance monitoring duration, the power converter circuit is configured to allow the terminal voltage to reach at a first preset overcharged value, and wherein in the second capacitance monitoring duration, the power converter circuit is configured to allow the terminal voltage to reach at a second preset overcharged value; and wherein the first preset overcharged value and the second preset overcharged value are higher than the preset storage value.

11. The power management circuit as claimed in claim 7, further including:
a timing circuit, configured to provide a time that it takes for the terminal voltage to decrease from a first threshold voltage to a second threshold voltage in the discharging period of the first capacitance monitoring duration, and further configured to provide a time that it takes for the terminal voltage to decrease from a third threshold voltage to a fourth threshold voltage in the discharging period of the second capacitance monitoring duration; wherein a difference between the third threshold voltage and the fourth threshold voltage has a proportional relationship with a difference between the first threshold voltage and the second threshold voltage.

12. The power management circuit as claimed in claim 11, wherein the third threshold voltage is equal to the first threshold voltage and the fourth threshold voltage is equal to the second threshold voltage.
